(19) United States
(12) Patent Application Publication
(10) Pub. No.: US 2025/0311123 A1
(43) Pub. Date: Oct. 2, 2025

(54) SOLID-STATE DRIVE (SSD) DEVICE

(71) Applicant: INNODISK CORPORATION, New Taipei City (TW)

(72) Inventor: Kai-Cheng Yu, New Taipei City (TW)

(73) Assignee: INNODISK CORPORATION, New Taipei City (TW)

(21) Appl. No.: 18/947,273

(22) Filed: Nov. 14, 2024

(30) Foreign Application Priority Data
Mar. 27, 2024 (TW) 113111486

(51) Int. Cl. H05K 5/02; H05K 7/20

(52) U.S. Cl. CPC H05K 5/0213; H05K 7/20136

(57) ABSTRACT

This disclosure provides a solid-state drive (SSD) device, including a casing, a memory mainboard, and a memory module board. The casing is provided with a plurality of ventilation holes to facilitate the discharge of heat from the SSD device through the ventilation holes. The memory mainboard is disposed inside the casing. The memory module board is disposed inside the casing, and is maintained at a different height from the memory mainboard, defining a ventilation channel between the memory mainboard and the memory module board.

### CROSS-REFERENCE TO RELATED APPLICATION AND CLAIM OF PRIORITY

The application claims the benefit of Taiwan Patent Application No. 113111486, filed on Mar. 27, 2024, at the Taiwan Intellectual Property Office, the disclosures of which are incorporated herein in their entirety by reference.

### FIELD OF THE DISCLOSURE

The present disclosure generally relates to a solid-state drive (SSD) device and, more particularly, to an SSD device with multiple circuit boards, which is capable of increasing the number of memory chips to enhance storage capacity and providing space for heat convection between the multiple circuit boards to improve cooling efficiency.

### BACKGROUND OF THE DISCLOSURE

Although conventional solid-state drive (SSD) devices offer significant advantages over hard disk drives (HDDs) in many aspects, such as faster boot times, higher read/write speeds, and better shock resistance, there are still some limitations in their design. In particular, an SSD with a single-layer circuit board and without effective cooling mechanisms faces challenges in enhancing storage capacity, which affects the performance of the SSD. This also limits their lifespan and reliability in high-demand application scenarios.

Firstly, many conventional SSD devices adopt a single circuit board design, which limits the possibility of adding more memory chips within a confined space, and thus the expansion of storage capacity is restricted. As the demand for data storage continues to grow, especially in enterprise applications and high-end consumer electronics, this design limitation of conventional SSDs has become a major obstacle to increasing storage capacity.

Secondly, the inadequate cooling mechanisms in conventional SSD devices pose challenges for maintaining long-term high-performance operations and ensuring the lifespan. SSD devices generate a significant amount of heat during high-speed operation. If the amount of heat cannot be sufficiently cooled, it will cause the device to overheat, which will affect the performance of the device and potentially damage the device. Moreover, overheating may accelerate the loss of the flash memory in the SSD, reducing its lifespan. Flash memory cells gradually lose reliability after a certain number of write and erase cycles. High temperatures can accelerate this process, negatively impacting the lifespan. Therefore, an effective cooling mechanism is crucial for maintaining the long-term performance and reliability of SSD devices.

Therefore, there is a need for an SSD device that meets the growing demands for data storage and performance requirements.

### SUMMARY OF THE DISCLOSURE

One of the objectives of the present disclosure is to provide a solid-state drive (SSD) device including circuit boards loaded with memory chips, wherein the circuit boards are configured in a stacked manner. In the solid-state drive (SSD) device of the present invention, the number of memory chips can be increased to enhance storage capacity, and space for heat convection between the stacked circuit boards can be provided to improve cooling efficiency.

To achieve the above objective, in one aspect, the present disclosure provides a solid-state drive (SSD) device, including a casing, a memory mainboard, and a first memory expansion board. The casing is provided with a plurality of ventilation holes and a fan. The casing includes a top plate, a bottom plate, a side plate, and a first intermediate plate. The first intermediate plate is disposed between the top plate and the bottom plate and is partially connected to the side plate, thereby dividing an interior space of the casing into at least two spaces. The memory mainboard is fixed to the bottom plate of the casing and includes a set of input/output pins, a control chip, and a first set of memory chips. The set of input/output pins is disposed on one lateral side of the memory mainboard and is electrically connected to the control chip. The control chip is mounted on one surface of the memory mainboard and is electrically connected to the first set of memory chips. The first memory expansion board is fixed to the first intermediate plate and includes a second set of memory chips. The second set of memory chips is disposed on one surface of the first memory expansion board and is electrically connected to the control chip through a first set of cables. The fan is configured to generate an airflow to dissipate from the SSD device the heat in the interior space of the casing through the ventilation holes.

In another aspect, the present disclosure further provides an SSD device, including a casing, a memory mainboard, and a first memory module board. The casing is provided with a plurality of ventilation holes and a fan. The casing includes a top plate, a bottom plate, a side plate and a first intermediate plate disposed between the top plate and the bottom plate. The first intermediate plate is partially connected to the side plate to divide an interior space of the casing into at least two spaces. The memory mainboard is fixed to the bottom plate of the casing and includes a set of input/output pins and a control chip. The set of input/output pins is disposed on one lateral side of the memory mainboard and is electrically connected to the control chip. The control chip is mounted on one surface of the memory mainboard control chip. The first memory module board is fixed to the first intermediate plate and includes a first set of memory chips. The first set of memory chips is disposed on one surface of the first memory module board and is electrically connected to the control chip through a first set of cables. The fan is configured to generate an airflow to dissipate from the SSD device the heat in the interior space of the casing through the ventilation holes.

In another aspect, the present disclosure further provides a solid-state drive (SSD) device, including a casing, a memory mainboard, and a memory module board. The casing has an interior space and is provided with a plurality of ventilation holes to dissipate from the SSD device the heat in the interior space through the ventilation holes. The memory mainboard is disposed in the interior space. The memory module board is disposed in the interior space and maintained at a different height from that of the memory mainboard, thereby defining a ventilation channel between the memory mainboard and the memory module board.

In summary, the SSD device of the present disclosure can achieve an increase in memory capacity by configuring the circuit boards loaded with memory chips in a stacked manner within the casing of the SSD device by using intermediate plates, which increases the number of memory chips to enhance storage capacity, and provides the space for heat convection between the stacked circuit boards to improve cooling efficiency.

Further explanations and advantages of the present disclosure can be found in the subsequent diagrams and embodiments, which will provide a clearer understanding of the technical solutions of the present disclosure.

### BRIEF DESCRIPTION OF THE DRAWINGS

The above objectives and advantages of the present disclosure will become more readily apparent to those skilled in the art upon reviewing the following detailed descriptions and the accompanying drawings.

FIG. 1 is a perspective view of an SSD device according to a first embodiment of the present disclosure.

FIG. 2 is an exploded view of the SSD device shown in FIG. 1.

FIG. 3 is a perspective view of an SSD device according to a second embodiment of the present disclosure.

FIG. 4 is a perspective view of an SSD device according to a third embodiment of the present disclosure.

FIG. 5 is a perspective view of an SSD device according to a fourth embodiment of the present disclosure.

### DETAILED DESCRIPTION OF THE PREFERRED EMBODIMENTS

Please refer to all figures of the present disclosure when reading the following detailed description, wherein all figures of the present disclosure demonstrate different embodiments of the present disclosure by showing examples, and help the skilled person in the art to understand how to implement the present disclosure. The present examples provide sufficient embodiments to demonstrate the spirit of the present disclosure, each embodiment does not conflict with the others, and new embodiments can be implemented through an arbitrary combination thereof, i.e., the present disclosure is not restricted to the embodiments disclosed in the present specification. Unless there are other restrictions defined in the specific example, the following definitions apply to the terms used throughout the specification.

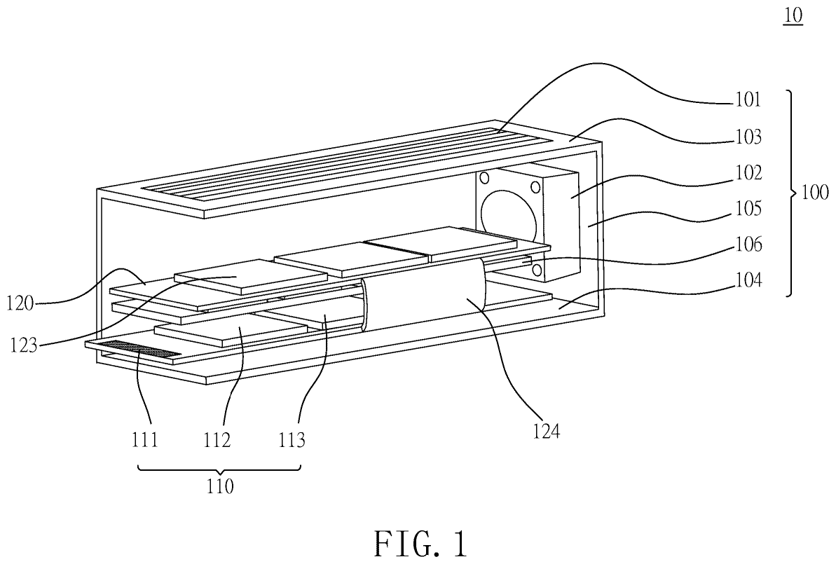

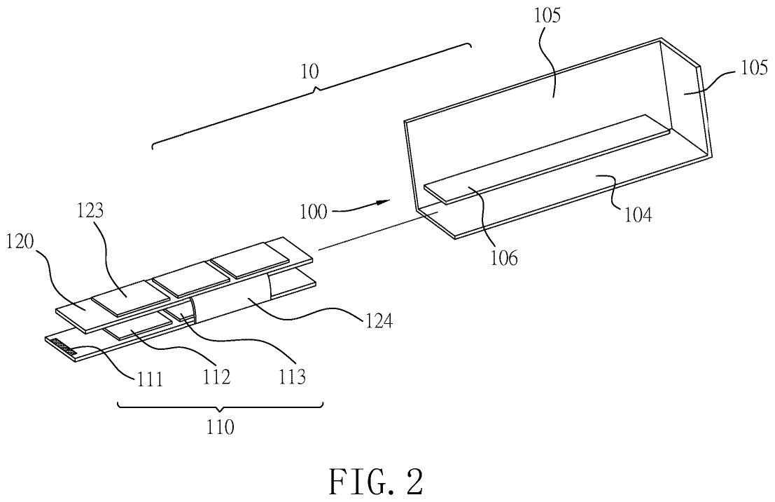

Please refer to FIG. 1 and FIG. 2, which are a perspective view and an exploded schematic view, respectively, of an SSD device according to a first embodiment of the present disclosure. In FIG. 1 and FIG. 2, the SSD device 10 in the first embodiment of the present disclosure includes a casing 100, a memory mainboard 110, and a first memory expansion board 120. The casing 100 is provided with a plurality of ventilation holes 101 and a fan 102. Moreover, the casing 100 includes a top plate 103, a bottom plate 104, a side plate 105, and a first intermediate plate 106. The first intermediate plate 106 is disposed between the top plate 103 and the bottom plate 104 and is partially connected to the side plate 105, thereby dividing an interior space of the casing 100 into at least two spaces. The memory mainboard 110 is fixed to the bottom plate 104 of the casing 100 and includes a set of input/output pins 111, a control chip 112, and a first set of memory chips 113. The set of input/output pins 111 is disposed on one lateral side of the memory mainboard 110 and is electrically connected to the control chip 112. The control chip 112 is mounted on one surface of the memory mainboard 110 and is electrically connected to the first set of memory chips 113. In some embodiments, the first set of memory chips 113 may be disposed on either or both surfaces of the memory mainboard 110. In some embodiments, the memory mainboard 110 may be fixed to the bottom plate 104 of the casing 100 using a plurality of pillars (not shown) or attached to the bottom plate 104 of the casing 100 via a thermal pad (not shown); however, the disclosure is not limited to such fixing methods.

To increase the memory capacity of the SSD device 10 of the present disclosure, the first memory expansion board 120 is added and is fixed to the first intermediate plate 106. The first memory expansion board 120 includes a second set of memory chips 123. The second set of memory chips 123 is disposed on one surface of the first memory expansion board 120 and is electrically connected to the control chip 112 through a first set of cables 124. In some embodiments, the second set of memory chips 123 may be disposed on either or both surfaces of the first memory expansion board 120. In some embodiments, the first set of cables 124 may be implemented using a rigid-flex board or a set of flexible cables; however, the disclosure is not limited to such configurations. In some embodiments, the first memory expansion board 120 may be fixed to the first intermediate plate 106 using a plurality of pillars (not shown) or attached to the first intermediate plate 106 via a thermal pad (not shown); however, the disclosure is not limited to such fixing methods.

In this embodiment, the fan 102 is configured to generate an airflow to dissipate from the SSD device 10 the heat in the interior space of the casing 100 through the ventilation holes 101.

As the configuration described above, the SSD device 10 of the first embodiment of the present disclosure uses a stacked configuration of circuit boards loaded with memory chips, which increases the number of memory chips to enhance storage capacity, and provides the space for heat convection between the stacked circuit boards to improve cooling efficiency.

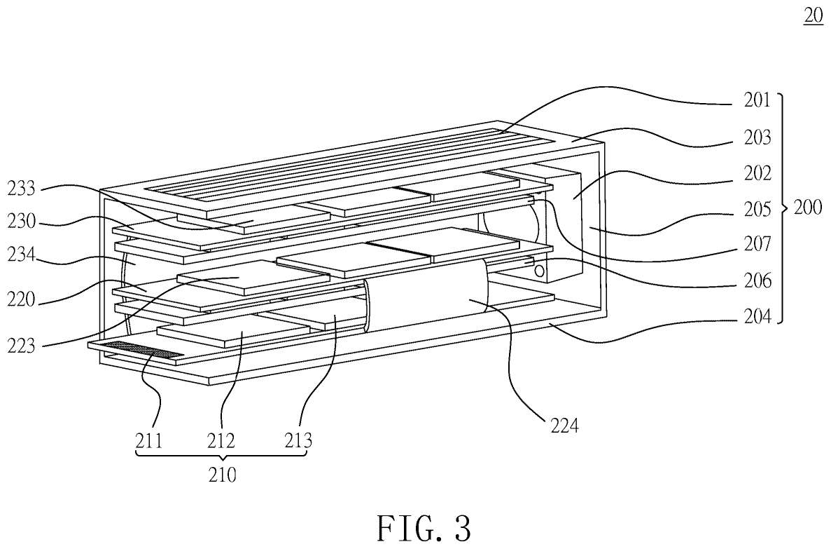

Please refer to FIG. 3, which is a perspective view of an SSD device according to a second embodiment of the present disclosure. In FIG. 3, the SSD device 20 of the second embodiment of the present disclosure includes a casing 200, a memory mainboard 210, a first memory expansion board 220, and a second memory expansion board 230. The casing 200 is provided with a plurality of ventilation holes 201 and a fan 202. Moreover, the casing 200 includes a top plate 203, a bottom plate 204, a side plate 205, a first intermediate plate 206, and a second intermediate plate 207. The first intermediate plate 206 and the second intermediate plate 207 are disposed parallel to each other between the top plate 203 and the bottom plate 204, and are partially connected to the side plates 205, thereby dividing an interior space of the casing 200 into three spaces. The memory mainboard 210 is fixed to the bottom plate 204 of the casing 200, and includes a set of input/output pins 211, a control chip 212 and a first set of memory chips 213. The set of input/output pins 211 is disposed on one lateral side of the memory mainboard 210 and is electrically connected to the control chip 212. The control chip 212 is mounted on one surface of the memory mainboard 210 and is electrically connected to the first set of memory chips 213. In some embodiments, the first set of memory chips 213 may be disposed on either or both surfaces of the memory mainboard 210. In some embodiments, the memory mainboard 210 may be fixed to the bottom plate 204 of the casing 200 using a plurality of pillars (not shown) or attached to the bottom plate 204 of the casing 200 via a thermal pad (not shown); however, the disclosure is not limited to such fixing methods.

In the second embodiment, to increase the memory capacity of the SSD device 20, the first memory expansion board 220 is added and is fixed to the first intermediate plate 206. The first memory expansion board 220 includes a second set of memory chips 223. The second set of memory chips 223 is disposed on one surface of the first memory expansion board 220 and is electrically connected to the control chip 212 through a first set of cables 224. In some embodiments, the second set of memory chips 223 may be disposed on either or both surfaces of the first memory expansion board 220. In some embodiments, the first set of cables 224 may be implemented using a rigid-flex board or a set of flexible cables; however, the disclosure is not limited to such configurations. In some embodiments, the first memory expansion board 220 may be fixed to the first intermediate plate 206 using a plurality of pillars (not shown) or attached to the first intermediate plate 206 via a thermal pad (not shown); however, the disclosure is not limited to such fixing methods.

In the second embodiment, to further increase the memory capacity of the SSD device 20, a second memory expansion board 230 is added and is fixed to the second intermediate plate 207. The second memory expansion board 230 includes a third set of memory chips 233. The third set of memory chips 233 is disposed on one surface of the second memory expansion board 230 and is electrically connected to the control chip 212 through a second set of cables 234. In some embodiments, the third set of memory chips 233 may be disposed on either or both surfaces of the second memory expansion board 230. In some embodiments, the second set of cables 234 may be implemented using a rigid-flex board or a set of flexible cables; however, the disclosure is not limited to such configurations. In some embodiments, the second memory expansion board 230 may be fixed to the second intermediate plate 207 using a plurality of pillars (not shown) or attached to the second intermediate plate 207 via a thermal pad (not shown); however, the disclosure is not limited to such fixing methods.

In the second embodiment, the fan 202 is configured to generate an airflow to dissipate from the SSD device 20 the heat in the interior space of the casing 200 through the ventilation holes 201.

As the configuration described above, the SSD device 20 of the second embodiment of the present disclosure uses a stacked configuration of circuit boards loaded with memory chips, which increases the number of memory chips to enhance storage capacity, and provides the space for heat convection between the stacked circuit boards to improve cooling efficiency.

In addition to the first and the second embodiments described above, the configuration of the SSD device of the present disclosure may have several variations. For example, in the second embodiment, the second memory expansion board 230 in FIG. 3 may also be directly fixed to the top plate 203, and thus the second intermediate plate 207 is unneeded. In some embodiments, the second memory expansion board 230 may be fixed to the top plate 203 using a plurality of pillars (not shown) or attached to the top plate 203 via a thermal pad (not shown); however, the disclosure is not limited to such fixing methods.

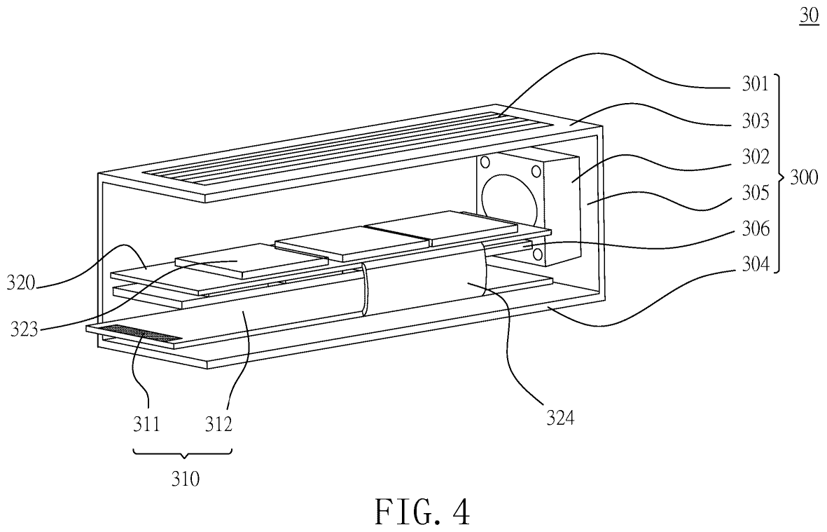

Please refer to FIG. 4, which is a perspective view of an SSD device according to a third embodiment of the present disclosure. In FIG. 4, the SSD device 30 of the third embodiment of the present disclosure includes a casing 300, a memory mainboard 310, and a first memory module board 320. The casing 300 is provided with a plurality of ventilation holes 301 and a fan 302. Moreover, the casing 300 includes a top plate 303, a bottom plate 304, a side plate 305, and a first intermediate plate 306. The first intermediate plate 306 is disposed between the top plate 303 and the bottom plate 304, and is partially connected to the side plates 305, thereby dividing an interior space of the casing 300 into at least two spaces. The memory mainboard 310 is fixed to the bottom plate 304 of the casing 300 and includes a set of input/output pins 311 and a control chip 312. The set of input/output pins 311 is disposed on one lateral side of the memory mainboard 310 and is electrically connected to the control chip 312. The control chip 312 is mounted on one surface of the memory mainboard 310. In some embodiments, the memory mainboard 310 may be fixed to the bottom plate 304 of the casing 300 using a plurality of pillars (not shown) or attached to the bottom plate 304 of the casing 300 via a thermal pad (not shown); however, the disclosure is not limited to such fixing methods.

In this embodiment, the first memory module board 320 is fixed to the first intermediate plate 306. The first memory module board 320 includes a first set of memory chips 323. The first set of memory chips 323 is disposed on one surface of the first memory module board 320 and is electrically connected to the control chip 312 through a first set of cables 324. In some embodiments, the first set of memory chips 323 may be disposed on either or both surfaces of the first memory module board 320. In some embodiments, the first set of cables 324 may be implemented using a rigid-flex board or a set of flexible cables; however, the disclosure is not limited to such fixing methods. In some embodiments, the first memory module board 320 may be fixed to the first intermediate plate 306 using a plurality of pillars (not shown) or attached to the first intermediate plate 306 via a thermal pad (not shown); however, the disclosure is not limited to such fixing methods.

In this embodiment, the fan 302 is configured to generate an airflow to dissipate from the SSD device 30 the heat in the interior space of the casing 300 through the ventilation holes 301.

As the configuration described above, the SSD device 30 of the first embodiment of the present disclosure uses a stacked configuration of circuit boards loaded with memory chips, which increases the number of memory chips to enhance storage capacity, and provides the space for heat convection between the stacked circuit boards to improve cooling efficiency.

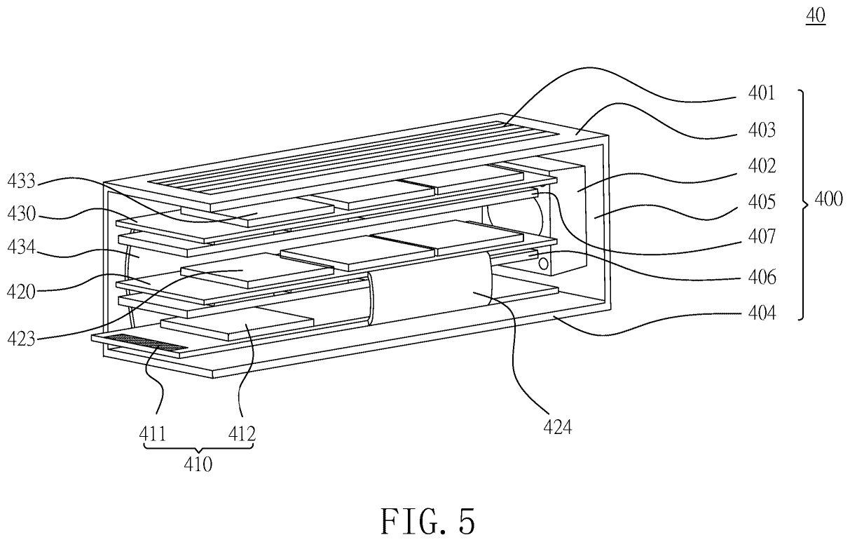

Please refer to FIG. 5, which is a perspective view of an SSD device according to a fourth embodiment of the present disclosure. In FIG. 5, the SSD device 40 of the fourth embodiment of the present disclosure includes a casing 400, a memory mainboard 410, a first memory expansion board 420, and a second memory expansion board 430. The casing 400 is provided with a plurality of ventilation holes 401 and a fan 402. Moreover, the casing 400 includes a top plate 403, a bottom plate 404, a side plate 405, a first intermediate plate 406, and a second intermediate plate 407. The first intermediate plate 406 and the second intermediate plate 407 are disposed parallel to each other between the top plate 403 and the bottom plate 404, and are partially connected to the side plates 405, thereby dividing an interior space of the casing 400 into three spaces. The memory mainboard 410 is fixed to the bottom plate 404 of the casing 400, and includes a set of input/output pins 411 and a control chip 412. The set of input/output pins 411 is disposed on one lateral side of the memory mainboard 410 and is electrically connected to the control chip 412. The control chip 412 is mounted on one surface of the memory mainboard 410. In some embodiments, the memory mainboard 410 may be fixed to the bottom plate 404 of the casing 400 using a plurality of pillars (not shown) or attached to the bottom plate 404 of the casing 400 via a thermal pad (not shown); however, the disclosure is not limited to such fixing methods.

In the fourth embodiment, the first memory module board 420 is fixed to the first intermediate plate 406. The first memory module board 420 includes a first set of memory chips 423. The first set of memory chips 423 is disposed on one surface of the first memory module board 420 and is electrically connected to the control chip 412 through a first set of cables 424. In some embodiments, the first set of memory chips 423 may be may be disposed on either or both surfaces of the first memory module board 420. In some embodiments, the first set of cables 424 may be implemented using a rigid-flex board or a set of flexible cables; however, the disclosure is not limited to such configurations. In some embodiments, the first memory module board 420 may be fixed to the first intermediate plate 406 using a plurality of pillars (not shown) or attached to the first intermediate plate 406 via a thermal pad (not shown); however, the disclosure is not limited to such fixing methods.

In the fourth embodiment, to further increase the memory capacity of the SSD device 40, a second memory module board 430 is added and is fixed to the second intermediate plate 407. The second memory module board 430 includes a second set of memory chips 433. The second set of memory chips 433 is disposed on one surface of the second memory module board 430 and is electrically connected to the control chip 412 through a second set of cables 434. In some embodiments, the second set of memory chips 433 may be disposed on either or both surfaces of the second memory module board 430. In some embodiments, the second set of cables 434 may be implemented using a rigid-flex board or a set of flexible cables; however, the disclosure is not limited to such configurations. In some embodiments, the second memory module board 430 may be fixed to the second intermediate plate 407 using a plurality of pillars (not shown) or attached to the second intermediate plate 407 via a thermal pad (not shown); however, the disclosure is not limited to such fixing methods.

In the fourth embodiment, the fan 402 is configured to generate an airflow to dissipate from the SSD device 40 the heat in the interior space of the casing 400 through the ventilation holes 401.

As the configuration described above, the SSD device 40 of the second embodiment of the present disclosure uses a stacked configuration of circuit boards loaded with memory chips, which increases the number of memory chips to enhance storage capacity, and provides the space for heat convection between the stacked circuit boards to improve cooling efficiency.

In addition to the third and the fourth embodiments described above, the configuration of the SSD device of the present disclosure may have several variations. For example, in the fourth embodiment, the second memory module board 430 in FIG. 5 can also be directly fixed to the top plate 403, and thus the second intermediate plate 407 is unneeded. In some embodiments, the second memory module board 430 may be fixed to the top plate 403 using a plurality of pillars (not shown) or attached to the top plate 403 via a thermal pad (not shown); however, the disclosure is not limited to such fixing methods.

From the above discussion, it is clear that the SSD device of the present disclosure can achieve an increase in memory capacity by configuring the circuit boards loaded with memory chips in a stacked manner within the casing of the SSD device by using intermediate plates, which increases the number of memory chips to enhance storage capacity, and provides the space for heat convection between the stacked circuit boards to improve cooling efficiency.

While the disclosure has been described in terms of what is presently considered to be the most practical and preferred embodiments, it is to be understood that the disclosure need not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A solid-state drive (SSD) device, comprising:
a casing provided with a plurality of ventilation holes and a fan and comprising a top plate, a bottom plate, a side plate and a first intermediate plate disposed between the top plate and the bottom plate, wherein the first intermediate plate is partially connected to the side plate to divide an interior space of the casing into at least two spaces;
a memory mainboard fixed to the bottom plate of the casing and comprising a set of input/output pins, a control chip, and a first set of memory chips, wherein the set of input/output pins is disposed on one lateral side of the memory mainboard and is electrically connected to the control chip, and the control chip is mounted on one surface of the memory mainboard and electrically connected to the first set of memory chips; and
a first memory expansion board, fixed to the first intermediate plate and comprising a second set of memory chips, wherein the second set of memory chips is disposed on one surface of the first memory expansion board and is electrically connected to the control chip through a first set of cables, wherein the fan is configured to generate an airflow to dissipate from the SSD device the heat in the interior space of the casing through the ventilation holes.

2. The SSD device of claim 1, further comprising:
a second intermediate plate partially connected to the side plate, such that the second intermediate plate is parallel to the first intermediate plate; and
a second memory expansion board fixed to the second intermediate plate and comprising a third set of memory chips, wherein the third set of memory chips is disposed on one surface of the second memory expansion board and is electrically connected to the control chip through a second set of cables.

3. The SSD device of claim 2, wherein the second set of cables is implemented using a rigid-flex board.

4. The SSD device of claim 2, wherein the second set of cables is implemented using a set of flexible cables.

5. The SSD device of claim 1, further comprising:
a second memory expansion board fixed to the top plate of the casing and comprising a third set of memory chips, wherein the third set of memory chips is disposed on one surface of the second memory expansion board and is electrically connected to the control chip through a second set of cables.

6. The SSD device of claim 5, wherein the second set of cables is implemented using a rigid-flex board.

7. The SSD device of claim 5, wherein the second set of cables is implemented using a set of flexible cables.

8. The SSD device of claim 1, wherein the first set of cables is implemented using a rigid-flex board.

9. The SSD device of claim 1, wherein the first set of cables is implemented using a set of flexible cables.

10. A solid-state drive (SSD) device, comprising:
a casing provided with a plurality of ventilation holes and a fan and comprising a top plate, a bottom plate, a side plate and a first intermediate plate disposed between the top plate and the bottom plate, wherein the first intermediate plate is partially connected to the side plate to divide an interior space of the casing into at least two spaces;
a memory mainboard fixed to the bottom plate of the casing and comprising a set of input/output pins and a control chip, wherein the set of input/output pins is disposed on one lateral side of the memory mainboard and is electrically connected to the control chip, and the control chip is mounted on one surface of the memory mainboard; and
a first memory module board fixed to the first intermediate plate and comprising a first set of memory chips, wherein the first set of memory chips is disposed on one surface of the first memory module board and is electrically connected to the control chip through a first set of cables,
wherein the fan is configured to generate an airflow to dissipate from the SSD device the heat in the interior space of the casing through the ventilation holes.

11. The SSD device of claim 10, further comprising:
a second intermediate plate partially connected to the side plate such that the second intermediate plate is parallel to the first intermediate plate; and
a second memory module board fixed to the second intermediate plate and comprising a second set of memory chips, wherein the second set of memory chips is disposed on one surface of the second memory module board and is electrically connected to the control chip through a second set of cables.

12. The SSD device of claim 11, wherein the second set of cables is implemented using a rigid-flex board.

13. The SSD device of claim 11, wherein the second set of cables is implemented using a set of flexible cables.

14. The SSD device of claim 11, further comprising:
a second memory module board fixed to the top plate of the casing and comprising a second set of memory chips, wherein the second set of memory chips is disposed on one surface of the second memory module board and is electrically connected to the control chip through a second set of cables.

15. The SSD device of claim 14, wherein the second set of cables is implemented using a rigid-flex board.

16. The SSD device of claim 14, wherein the second set of cables is implemented using a set of flexible cables.

17. The SSD device of claim 10, wherein the first set of cables is implemented using a rigid-flex board.

18. The SSD device of claim 10, wherein the first set of cables is implemented using a set of flexible cables.

19. A solid-state drive (SSD) device, comprising:
a casing having an interior space, provided with a plurality of ventilation holes, and dissipating from the SSD device the heat in the interior space through the ventilation holes;
a memory mainboard disposed in the interior space; and
a memory module board disposed in the interior space and maintained at a different height from that of the memory mainboard, thereby defining a ventilation channel between the memory mainboard and the memory module board.

20. The SSD device of claim 19, wherein the memory mainboard comprises a set of input/output pins electrically connected to a control chip and the memory module board comprises a set of memory chips electrically connected to the control chip through a first set of cables.
